(19) United States
(12) Patent Application Publication
(10) Pub. No.: US 2025/0112606 A1
(43) Pub. Date: Apr. 3, 2025

(54) PROGRAMMABLE GAIN TRANSIMPEDANCE AMPLIFIER HAVING A RESISTIVE T-NETWORK FEEDBACK ARCHITECTURE AND METHOD THEREOF

(71) Applicant: BAE Systems Information and Electronic Systems Integration Inc., Nashua, NH (US)

(72) Inventor: Gregory S. Notaro, Bedford, NH (US)

(73) Assignee: BAE Systems Information and Electronic Systems Integration Inc., Nashua, NH (US)

(21) Appl. No.: 18/477,116

(22) Filed: Sep. 28, 2023

(51) Int. Cl. H03G 3/30; H03F 3/45

(52) U.S. Cl. CPC H03G 3/30; H03F 3/45076; H03F 2200/144; H03F 2200/387; H03F 2203/45116; H03F 2203/45512; H03G 2201/103

(57) ABSTRACT

A programmable transimpedance amplifiers (TIA) having T-network feedback architectures for achieving varying levels of gain based on a magnitude of an input current signal. TIA includes an operational amplifier (op-amp), a first or T-network feedback architecture that operatively connects with the op-amp at a first input terminal of the op-amp and the output terminal of the op-amp, a second feedback architecture that operatively connects with the op-amp at the first input terminal of the operational amplifier and the output terminal of the operational amplifier, an input voltage source architecture that operatively connects with a second input terminal of the operational amplifier, and at least one controller that operatively connects with each of the first feedback architecture, the second feedback architecture, and the input voltage source architecture to switch specific architectures between operative states and inoperative states to achieve a predetermined fixed output bias voltage from the operational amplifier.

### STATEMENT OF GOVERNMENT INTEREST

This invention was made with government support under subcontract number 4PO-19069 awarded by the United States Air Force. The government has certain rights in the invention.

### TECHNICAL FIELD

The present disclosure relates to a transimpedance amplifiers having T-network feedback architectures for achieving varying levels of gain based on a magnitude of an input current signal.

### BACKGROUND ART

In the electronics art, transimpedance amplifiers (hereinafter TIAs) are electrical current to electrical voltage converter circuits that are most often implemented using operational amplifiers. Currently, TIAs can be used to amplify the electrical current output of Geiger-Müller tubes, photo multiplier tubes, accelerometers, photo detectors (e.g., photodiodes), and other types of sensors that have a current response that is more linear than the voltage response. In most TIAs, TIAs convert the low-level current of a sensor into a voltage at a specific gain and bandwidth. As such, the gain, bandwidth, and current and voltage offsets change with different types of sensors requiring different configurations of TIAs.

Per these requirements, however, designers of TIAs are faced with numerous variables and/or issues when designing these TIAs, specifically varying magnitudes of input current signals inputted into these TIAs. In order to maximize signal-to-noise ratio (SNR) and dynamic range of these TIAs, these TIAs should include a relatively high gain configuration in situations where input current signal is rather small or low. Moreover, these TIAs require a relatively high analog signal bandwidth, which is difficult to manage with relatively high levels of gain with standard transimpedance amplifier topologies.

To combat these issues, designers of TIAs may use T-network feedback architectures in order to design high gain configurations resulting in variable output direct current (DC) biases when a fixed DC input common mode voltage is applied to a non-inverting input of an operational amplifier of these TIAs. However, incorporating such T-network feedback architectures into TIA configurations may prevent the T-network feedback architectures from behaving as unity gain buffers at low frequencies and will therefore amplify the fixed DC input common mode voltage.

### SUMMARY OF THE INVENTION

In one aspect, an exemplary embodiment of the present disclosure may provide a programmable transimpedance amplifier system (TIA). TIA includes an operational amplifier having a first input terminal, a second input terminal, and an output terminal. TIA also includes a first feedback architecture that operatively connects with the operational amplifier at the first input terminal of the operational amplifier and the output terminal of the operational amplifier, the first feedback architecture has a first impedance network and a second impedance network. TIA also includes a second feedback architecture that operatively connects with the operational amplifier at the first input terminal of the operational amplifier and the output terminal of the operational amplifier. TIA also includes an input voltage source architecture that operatively connects with the second input terminal of the operational amplifier. TIA also includes at least one controller that operatively connects with each of the first feedback architecture, the second feedback architecture, and the input voltage source architecture. The at least one controller is configured to switch each of the first feedback architecture, the second feedback architecture, and the input voltage source architecture between an operative state and an inoperative state to achieve a predetermined fixed output bias voltage from the operational amplifier.

This exemplary embodiment or another exemplary embodiment may further include a first set of switches operatively connected with a first input common voltage power source of the input voltage source architecture, the second feedback architecture, and the at least one controller; and a second set of switches operatively connected with the first feedback architecture, a second input common voltage power source of the input voltage source architecture, and at least another controller. This exemplary embodiment or another exemplary embodiment may further include a first input common mode voltage outputted from the first input common voltage power source to the operational amplifier and the second feedback architecture when the at least one controller switches the first set of switches from open states to closed states; wherein the second feedback architecture and the first input common voltage power source are in the operative state. This exemplary embodiment or another exemplary embodiment may further include an output voltage outputted from the operational amplifier and the second feedback architecture; wherein the first input common mode voltage and the output voltage are equal to one another. This exemplary embodiment or another exemplary embodiment may further include a second input common mode voltage outputted from the second input common voltage power source to the operational amplifier and the first feedback architecture when the at least another controller switches the second set of switches from open states to closed states; wherein the first feedback architecture and the second input common voltage power source are in the operative state. This exemplary embodiment or another exemplary embodiment may further include an output voltage outputted from the operational amplifier and the second feedback architecture; wherein the second input common mode voltage and the output voltage are different from one another. This exemplary embodiment or another exemplary embodiment may further include that the first set of switches comprises: a first switch operatively connected with and in series with an output terminal of the first input common voltage power source and operatively connected with the second input terminal of the operational amplifier; and a second switch operatively connected with and in series with an output terminal of the second feedback architecture and operatively connected with the first input terminal of the operational amplifier; wherein the first switch and the second switch are configured to be switched concurrently between open states and closed states. This exemplary embodiment or another exemplary embodiment may further include that the second feedback architecture comprises: a capacitor operatively connected with the output terminal of the operational amplifier; and a resistor operatively connected with the output terminal of the operational amplifier; wherein the capacitor and the resistor are in parallel with one another and are in series with the second switch. This exemplary embodiment or another exemplary embodiment may further include that the second set of switches comprises: a first switch operatively connected with and in series with an output terminal of the second input common voltage power source and operatively connected with the second input terminal of the operational amplifier; and a second switch operatively connected with and in series with an output terminal of the first feedback architecture and operatively connected with the first input terminal of the operational amplifier; wherein the first switch and the second switch are configured to be switched concurrently between open states and closed states by the at least another controller. This exemplary embodiment or another exemplary embodiment may further include that the first feedback architecture further comprises: a capacitor of the first impedance network operatively connected with the output terminal of the operational amplifier; and a resistor of the first impedance network operatively connected with the output terminal of the operational amplifier; wherein the capacitor of the first impedance network and the resistor of the first impedance network are in parallel with one another and are in series with the second impedance network and the second switch. This exemplary embodiment or another exemplary embodiment may further include that the first feedback architecture further comprises: a capacitor of the second impedance network operatively connected with the output terminal of the operational amplifier; and a resistor of the second impedance network operatively connected with the output terminal of the operational amplifier; wherein the capacitor of the second impedance network and the resistor of the second impedance network are in parallel with one another and are in series with the second switch. This exemplary embodiment or another exemplary embodiment may further include that the first feedback architecture further comprises: a ground resistor operatively connected with an output of the first impedance network and operatively connected with an input of the second impedance network. This exemplary embodiment or another exemplary embodiment may further include a parasitic capacitor in series with the second feedback architecture and operatively connected with the first input terminal of the operational amplifier.

In another aspect, an exemplary embodiment of the present disclosure may provide a method. The method includes steps of: receiving an input current, from a signal generating device, at a first input terminal of an operational amplifier; inputting at least one input common mode voltage signal, by an input voltage source architecture, to a second input terminal of the operational amplifier; converting the input current to a first output voltage with a first gain value via the operational amplifier; outputting the first output voltage, via the operational amplifier, from an output terminal of the operational amplifier to a first feedback architecture; outputting a second output voltage with a second gain value, by the first feedback architecture, to the first input terminal of the operational amplifier, wherein the second gain value is equal with the first gain value; outputting a third output voltage with a third gain value, via the operational amplifier, from the output terminal of the operational amplifier to a second feedback architecture; and outputting a fourth output voltage with a fourth gain value, from the second feedback architecture, to the first input terminal of the operational amplifier, wherein the fourth gain value is different than the first and third gain values.

This exemplary embodiment or another exemplary embodiment may further include steps of actuating a first set of switches, via at least one controller, from open states to closed states; and maintaining a second set of switches, via at least another controller, at open states. This exemplary embodiment or another exemplary embodiment may further include that the step of actuating the first set of switches further comprises: actuating a first switch of the first set of switches, via the at least one controller, from a first open state to a first closed state, to provide electrical communication between the operational amplifier and a first input common mode voltage source of the input voltage source architecture; and actuating a second switch of the first set of switches, via the at least one controller, from a second open state to a second closed state, to provide electrical communication between the operational amplifier and the first feedback architecture. This exemplary embodiment or another exemplary embodiment may further include steps of maintaining the first set of switches, via at least one controller, at open states; and actuating the second set of switches, via the at least another controller, from the open states to closed states. This exemplary embodiment or another exemplary embodiment may further include that the step of actuating the second set of switches further comprises: actuating a first switch of the second set of switches, via the at least another controller, from a first open state to a first closed state, to provide electrical communication between the operational amplifier and a second input common mode voltage source of the input voltage source architecture; and actuating a second switch of the second set of switches, via the at least another controller, from a second open state to a second closed state, to provide electrical communication between the operational amplifier and the second feedback architecture. This exemplary embodiment or another exemplary embodiment may further include steps of actuating the first set of switches, via the at least one controller, from the closed states to the opened states; and maintaining a second set of switches, via at least another controller, at the closed states. This exemplary embodiment or another exemplary embodiment may further include that the step of actuating the first set of switches further comprises: actuating a first switch of the first set of switches, via the at least one controller, from a first open state to a first closed state, to impede electrical communication between the operational amplifier and a first input common mode voltage source of the input voltage source architecture; and actuating a second switch of the first set of switches, via the at least one controller, from a second open state to a second closed state, to impede electrical communication between the operational amplifier and the first feedback architecture.

### BRIEF DESCRIPTION OF THE DRAWINGS

Sample embodiments of the present disclosure are set forth in the following description, are shown in the drawings and are particularly and distinctly pointed out and set forth in the appended claims.

FIG. 1 (FIG. 1) circuit diagram of a transimpedance amplifier system (TIA) in accordance with one aspect of the present disclosure.

FIG. 2A (FIG. 2A) is an operational view of the TIA, wherein a first controller of the TIA actuates a set of first switches from open positions to closed positions so a first input common mode voltage source outputs a first fixed direct current (DC) common mode voltage signal.

FIG. 2B (FIG. 2B) is another operational view similar to FIG. 2A, but a second controller of the TIA actuates a set of second switches from open positions to closed positions so a second input common mode voltage source outputs a second fixed direct current (DC) common mode voltage signal.

FIG. 2C (FIG. 2C) is another operational view similar to FIG. 2B, but the first controller of the TIA actuates the set of first switches from the closed positions to the open positions so the first input common mode voltage source is prevented from outputting the first fixed direct current (DC) common mode voltage signal.

FIG. 3 (FIG. 3) is a method flowchart.

Similar numbers refer to similar parts throughout the drawings.

### DETAILED DESCRIPTION

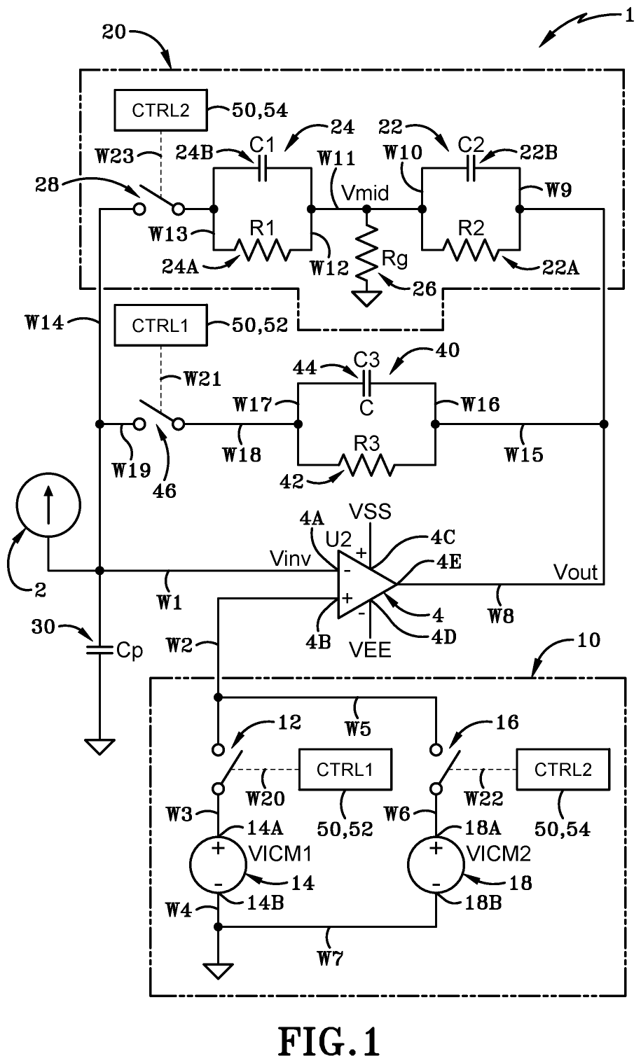

FIG. 1 illustrates a transimpedance amplifier system (hereinafter referred to “TIA”) which is generally referred to as 1. In the illustrated embodiment, the TIA 1 may include a fixed high gain setting and fixed low gain setting, which is described in more detail below. The TIA 1 may also be a programmable gain TIA that includes a fixed high gain setting and fixed low gain setting controlled by at least one ON and OFF control component that is suitable for a TIA. In one exemplary embodiment, a TIA may include an ON and OFF control component that is a solid state switch. In another exemplary embodiment, a TIA may include an ON and OFF control component that is at least one transistor. In another exemplary embodiment, any suitable electrical component and/or device may be used that is capable of providing an ON and OFF control component to switch between a high gain setting and a low gain setting for the TIA.

It should be understood that any suitable electrical connection may be used to electrically connect devices and/or components in the TIA 1 with one another. As such, any common or conventional electrical connection may be used herein to electrically connect devices and/or components in the TIA 1 with one another for transferring signals, power, and other information inside of the TIA 1 during operation.

Referring to FIG. 1, TIA 1 includes at least one signal sensing device or sensor 2. The at least one sensor 2 collects data and/or information based on the specific design of the at least one signal sensing device 2. Upon collecting this data, the at least one sensor 2 converts the collected data into an electrical current to be used in the TIA 1. In the illustrated embodiment, the at least one sensor 2 is a photodiode device that is capable of receiving a light signal (i.e., data and/or information) and converting said light signal into an electrical current for the TIA 1. In other exemplary embodiments, any suitable signal sensing device or sensor may be used in a TIA described and illustrated herein for collecting data and/or information per its designated function and converting said collected data and/or information into an electrical current signal. Examples of suitable signal sensing devices or sensors include Avalanche photodiodes, P-N photodiodes, PIN photodiodes, Schottky photodiodes, and other suitable signal sensing devices or sensors for collecting data and/or information per its designated function and converting said collected data and/or information into an electrical current signal. In another exemplary embodiment, at least one sensor may have any associated polarity based on the application of the at least one sensor in a TIA.

Still referring to FIG. 1, TIA 1 includes at least one operational amplifier 4 (hereinafter referred to “op-amp”) electrically connected with the at least one sensor 2, which is described in more detail below. The op-amp 4 provided herein is arranged in a non-inverting configuration that includes a first input terminal or inverting terminal 4A, a second input terminal or non-inverting terminal 4B, a first voltage input or voltage positive input 4C, a second voltage input or voltage negative input 4D, and a voltage output terminal 4E. Additionally, the op-amp 4 described and illustrated herein is an ideal op-amp that includes ideal characteristics associated with the operation of the op-amp 4 (e.g., infinite open-lop gain, infinite input impedance, zero output impedance, infinite bandwidth, zero noise, etc.).

Referring to FIG. 1, the at least one sensor 2 is operatively connected with the op-amp 4. Specifically, the at least one sensor 2 is electrically connected with the op-amp 4 via a first electrical connection W1. As illustrated in FIG. 1, the first electrical connection W1 connects an output of the at least one sensor 2 to the first input terminal 4A of the op-amp 4. With this electrical connection, the at least one sensor 2 outputs an electrical current signal to the op-amp 4 via the first electrical connection W1. Additionally, the op-amp 4 is powered at the first voltage input 4C and the second voltage input 4D via a power source (not illustrated herein).

Still referring to FIG. 1, TIA 1 also includes a common mode voltage source architecture (hereinafter “input voltage source architecture” generally referred to as 10. As discussed in greater detail below, the input voltage source architecture 10 includes at least two direct current (DC) voltage sources that provide fixed DC input common mode voltage signals to the op-amp 4. The input voltage source architecture 10 also includes components that may switch between the at least two DC voltage sources to adjust and/or maintain an output DC bias level of TIA 1. Such components and devices that form the input voltage source architecture 10 are discussed in greater detail below.

In the present disclosure, input voltage source architecture 10 includes a first switch 12 that is electrically connected with the op-amp 4. As best seen in FIG. 1, the first switch 12 is electrically connected with the op-amp 4, via a second electrical connection W2, where an output terminal of the first switch 12 is in series with the second input terminal 4B of the op-amp 4.

Still referring to FIG. 1, input voltage source architecture 10 also includes a first input common mode voltage source 14. The first input common mode voltage source 14 may be electrically connected with the op-amp 4 based on the electrical state and/or position of the first switch 12. In the present disclosure, the first input common mode voltage source 14 is electrically connected with the first switch 12 via a third electrical connection W3 where a positive terminal 14A of the first input common mode voltage source 14 is in series with an input terminal of the first switch 12. The first input common mode voltage source 14 is also electrically connected to the ground connection via a fourth electrical connection W4 where a negative terminal 14B of the first input common mode voltage source 14 is in series with the ground connection.

In operation, the first input common mode voltage source 14 may electrically communicate with the op-amp 4 based on the electrical state of the first switch 12. In one instance, the first input common mode voltage source 14 electrically communicates with and outputs a first input common mode voltage signal to the op-amp 4, via the second electrical connection W2 and the third electrical connection W3, when the first switch 12 is provided in a closed state. In another instance, the first input common mode voltage source 14 is impeded to electrically communicate with and deliver the first input common mode voltage signal to the op-amp 4, via the second electrical connection W2 and the third electrical connection W3, when the first switch 12 is provided in an open state. Such operation of the first input common mode voltage source 14 is discussed in greater detail below.

Still referring to FIG. 1, input voltage source architecture 10 also includes a second switch 16 that is electrically connected with the op-amp 4. Particularly, the second switch 16 is electrically connected with the op-amp 4 via a fifth electrical connection W5 where an output terminal of the second switch 16 is in series with the second input terminal 4B. Such operation of the second switch 16 in input voltage source architecture 10 is discussed in greater detail below.

Still referring to FIG. 1, input voltage source architecture 10 also includes a second input common mode voltage source 18. The second input common mode voltage source 18 may be electrically connected with the op-amp 4 based on the electrical state and/or position of the second switch 16. In the present disclosure, the second input common mode voltage source 18 is electrically connected with the second switch 16 via a sixth electrical connection W6 where a positive terminal 18A of the second input common mode voltage source 18 is in series with an input terminal of the second switch 16. The second input common mode voltage source 18 is also electrically connected to the ground connection via a seventh electrical connection W7 where a negative terminal 18B of the second input common mode voltage source 18 is in series with the ground connection.

In operation, the second input common mode voltage source 18 may electrically communicate with the op-amp 4 based on the electrical state of the second switch 16. In one instance, the second input common mode voltage source 18 electrically communicates with and outputs a second input common mode voltage signal to the op-amp 4, via the second electrical connection W2, the fifth electrical connection W5, and the sixth electrical connection W6, when the second switch 16 is provided in a closed state. In another instance, the second input common mode voltage source 18 is impeded from electrically communicating with and outputting a second input common mode voltage signal to the op-amp 4, via the second electrical connection W2, the fifth electrical connection W5, and the sixth electrical connection W6, when the second switch 16 is provided in an open state. Such operation of the second input common mode voltage source 18 is discussed in greater detail below.

In an exemplary embodiment, TIA 1 may include a signal alternating current (AC) input source (not illustrated herein) that electrically connects with the second input terminal 4B of the op-amp 4 and an input terminal of the input voltage source architecture 10 such that the AC input source is in series with the op-amp 4 and the input voltage source architecture 10. In this exemplary embodiment the AC input source may output an AC signal superimposed over the direct current (DC) common mode voltage that is applied and swept over a frequency range to measure the noise gain transfer function of TIA 1.

In TIA 1, each of the first input common mode voltage source 14 and the second input common mode voltage source 18 delivers an equivalent voltage to the op-amp 4 in the TIA 1 due to the TIA 1 using a negative feedback loop, which is described in further detail below. As such, each of the first input common mode voltage source 14 and the second input common mode voltage source 18 assists in the prevention of generating distorted output signals in TIA 1 by managing the input voltage being delivered into the op-amp 4 during operation. As described and illustrated herein, TIA 1 includes a bi-polar voltage supply application where a DC input common mode voltage is not required. During operation, any DC input common mode voltage applied by the first input common mode voltage source 14 or the second input common mode voltage source 18 will be amplified by the DC noise gain of the TIA 1 and is managed appropriately, which is described in more detail below.

In other exemplary embodiments, any suitable number of voltage sources may be used in a TIA described and illustrated herein. In one instance, a TIA may include a single common mode voltage source where the single common mode voltage source provides a DC input common mode bias. This DC input common mode bias may be applied via the common mode voltage source to accommodate for limited operational input voltage range of an op-amp and/or input common mode restrictions. In this instance, the input common mode voltage from the common mode voltage source may also provide a DC output offset bias for downstream electronics in the circuit.

Still referring to FIG. 1, TIA 1 includes a first feedback network or T-network feedback architecture 20 (hereinafter referred to as “T-network”) that is electrically connected with the op-amp 4. As described in more detail below, the T-network 20 and the op-amp 4 are electrically connected in parallel with one another in TIA 1. The T-network 20 is capable of managing the DC input common mode voltage applied by the input voltage source architecture 10 which is then amplified by the DC noise gain of the TIA 1. As such, the DC noise gain will be non-unity and will result in amplification of this DC voltage by implementing the T-network 20 described and illustrated herein. Additionally, the gain can be controlled by proper sizing of the resistors in the T-network 20, which is described in more detail below.

Still referring to FIG. 1, the T-network 20 includes a first impedance network 22 that is operatively engaged with the op-amp 4. Specifically, the first impedance network 22 is electrically connected with the op-amp 4 via an eighth electrical connection W8 where the output terminal 4E of the op-amp 4 is in series with an input of the first impedance network 22. In the illustrated embodiment, the first impedance network 22 includes a first resistor 22A that is electrically connected with the op-amp 4 via the eighth electrical connection W8 at an input terminal of the first resistor 22A. The first resistor 22A of the first impedance network 22 also defines a first resistance value “R1” as shown in FIG. 1. The first impedance network 22 also includes a first capacitor 22B that is electrically connected with the op-amp 4 via the eighth electrical connection W8 at an input terminal of the first capacitor 22B. The first capacitor 22B of the first impedance network 22 also defines a first capacitance value “C1” as shown in FIG. 1.

Still referring to FIG. 1, the first resistor 22A and the first capacitor 22B of the first impedance network 22 are also electrically connected in parallel with one another via a ninth electrical connection W9 and a tenth electrical connection W10. Specifically, the ninth electrical connection W9 electrically connects the input terminal of the first resistor 22A with the input terminal of the first capacitor 22B, and the tenth electrical connection W10 electrically connects an output terminal of the first resistor 22A with an output terminal of the first capacitor 22B.

In the present disclosure, the first impedance network 22 may also include a first parasitic capacitance (not illustrated) that is generated within the first impedance network 22 via the first capacitor 22B. The first parasitic capacitance of the first capacitor 22B is a first parasitic capacitance value which is less than the first capacitance value C1 of the first capacitor 22B.

Still referring to FIG. 1, the T-network 20 includes a second impedance network 24 that is electrically connected with the first impedance network 22. Specifically, the second impedance network 24 is electrically connected with the first impedance network 22 via an eleventh electrical connection W11 where an output terminal of the first impedance network 22 is in series with an input of the second impedance network 24.

In the illustrated embodiment, the second impedance network 24 includes a second resistor 24A that is electrically connected with the first impedance network 22 via the eleventh electrical connection W11 at an input terminal of the second resistor 24A. The second resistor 24A of the second impedance network 24 also defines a second resistance value “R2” as shown in FIG. 1. In the present disclosure, the second resistance value “R2” of the second resistor 24A is substantially equal with the first resistance value “R1” of the first resistor 22A.

In other exemplary embodiments, first and second resistors of first and second impedance networks may define any suitable resistance values for a TIA based on various considerations, including the desired gain needed to be generated in the TIA. In one exemplary embodiment, a first resistor value of a first resistor of a first impedance network may be greater than a second resistor value of a second resistor of a second impedance network. In another exemplary embodiment, a first resistor value of a first resistor of a first impedance network may be less than a second resistor value of a second resistor of a second impedance network. In another exemplary embodiment, a first resistor value of a first resistor of a first impedance network may be equal to a second resistor value of a second resistor of a second impedance network

Still referring to FIG. 1, the second impedance network 24 also includes a second capacitor 24B that is electrically connected with the first impedance network 22 via the eleventh electrical connection W11 at an input terminal of the second capacitor 24B. The second capacitor 24B of the second impedance network 24 also defines a second capacitance value “C2” as shown in FIG. 1. In the present disclosure, the second capacitance value “C2” of the second capacitor 24B is substantially equal with the first capacitance value “C1” of the first capacitor 22B.

In other exemplary embodiments, first and second capacitors of first and second impedance networks may define any suitable capacitance values for a TIA based on various considerations, including the parasitic capacitance generated by electrical components electrically connected in the TIA (e.g., photodiode junction capacitance, PCB trace capacitance, input differential, and common mode capacitance of the op-amp, and solid state switch capacitance). In one exemplary embodiment, a first capacitance value of a first capacitor of a first impedance network may be greater than a second capacitance value of a second capacitor of a second impedance network. In another exemplary embodiment, a first capacitance value of a first capacitor of a first impedance network may be less than a second capacitance value of a second capacitor of a second impedance network. In another exemplary embodiment, a first capacitance value of a first capacitor of a first impedance network may be equal to a second capacitance value of a second capacitor of a second impedance network.

Still referring to FIG. 1, the second resistor 24A and the second capacitor 24B of the second impedance network 24 are also electrically connected in parallel with one another via a twelfth electrical connection W12 and a thirteenth electrical connection W13. Specifically, the twelfth electrical connection W12 electrically connects the input terminal of the second resistor 24A with the input terminal of the second capacitor 24B, and the thirteenth electrical connection W13 electrically connects an output terminal of the second resistor 24A with an output terminal of the second capacitor 24B.

Still referring to FIG. 1, the second impedance network 24 also includes a second parasitic capacitance (not illustrated herein) that is generated within the second impedance network 24 via the second capacitor 24B. In the present disclosure, the second parasitic capacitance defines a second parasitic capacitance value that is less than the second capacitance value “C2” of the second capacitor 24B.

The use of the first capacitor 22B in the first impedance network 22 and the second capacitor 24B in the second impedance network 24 is considered advantageous at least because the first and second capacitors 22B, 24B improve stability of the outputted voltage signal and compensate the T-network feedback architecture 20 when parasitic capacitance is generated in the closed loop of TIA 1 by applying appropriate amounts of phase boost compensation in order to counteract the phase lag induced by parasitic capacitance. In comparison to previous known TIA, the inclusion of the first and second capacitors 22B, 24B in the first and second impedance networks 22, 24 presented herein introduces two poles for the noise gain of TIA 1 while also setting the signal bandwidth in TIA 1, which is described in more detail below. Moreover, the equivalent capacitance values “C1”, “C2” of the first and second capacitors 22B, 24B in the first and second impedance networks 22, 24 mitigates and/or minimizes against the potential parasitic capacitance that causes detrimental effects from a signal bandwidth generated by the at least one sensor 2, the op-amp 4, and the first and second capacitors 22B, 24B in TIA 1. The inclusion of the first and second capacitors 22B, 24B also provides a pole-zero cancellation effect that mitigates for additional phase lag induced by a second zero in the noise gain transfer function.

Still referring to FIG. 1, T-network 20 also includes a third or ground resistor 26 that is operatively engaged with the first impedance network 22 and the second impedance network 24. Specifically, the third resistor 26 is electrically connected with the first impedance network 22 via the eleventh electrical connection W11 at the output terminal of the first impedance network 22 and an input terminal of the third resistor 26. The third resistor 26 is also electrically connected with the second impedance network via the eleventh electrical connection W11 at the input terminal of the second impedance network 24 and the input terminal of the third resistor 26. The third resistor 26 is also electrically connected to ground at an output terminal of the third resistor 26.

Still referring to FIG. 1, the third resistor 26 defines a third resistance value “Rg”. In the present disclosure, the third resistance value “Rg” of the third resistor 26 is less than the first resistance value “R1” of the first resistor 22A of the first impedance network 22 and less than the second resistance value “R2” of the second resistor 24B of the second impedance network 24. In other exemplary embodiments, a third resistance value of a third resistor may have any suitable resistance value relative to a first resistance value of a first resistor of a first impedance network and/or a second resistance value of a second resistor of a second impedance network. In one exemplary embodiment, a third resistance value of a third resistor is greater than a first resistance value of a first resistor of a first impedance network and/or a second resistance value of a second resistor of a second impedance network.

The equivalent resistance values “R1” and “R2” of the first and second resistors 22A, 24A of the first and second impedance networks 22, 24 along with the first and second capacitors 24A, 24B is considered advantageous at least because these networks 22, 24 provide design freedom to minimize power consumption of TIA 1 while also maintaining appropriate compensation of function in TIA 1. The equivalent resistance values “R1” and “R2” of the first and second resistors 22A, 24A of the first and second impedance networks 22, 24 along with the first and second capacitors 24A, 24B also alleviates impacts from parasitic capacitances generated by components in TIA 1 and other components or circuit electrically connected with TIA 1.

Still referring to FIG. 1, TIA 1 also includes a third or T-network switch 28 that is electrically connected with the T-network 20. Particularly, the third switch 28 is electrically connected with the second impedance network 24 of T-network 28 via the thirteenth electrical connection W13 where an input terminal of the third switch 28 is in series with the output terminal of the T-network 20 and/or the output terminal of the second impedance network 24. The third switch 28 is electrically connected with the first input terminal 4A of the op-amp 4 via a fourteenth electrical connection W14 where an output terminal of the third switch 28 is in series with the first input terminal 4A of the op-amp 4.

In operation, the T-network 20 may electrically communicate with the first input terminal 4A of the op-amp 4 based on the electrical state of the third switch 28. In one instance, the T-network 20 electrically communicates with the first input terminal 4A of the op-amp 4, via the first electrical connection W1 and the fourteenth electrical connection W14, when the third switch 28 is provided in a closed state. Such electrical communication between the op-amp 4 and the second impedance network 24 provides a negative feedback loop for the op-amp 4 when the third switch 28 is provided in the closed state. In another instance, the T-network 20 is impeded from electrically communicating with the first input terminal 4A of the op-amp 4, via the first electrical connection W1 and the fourteenth electrical connection W14, when the third switch 28 is provided in an open state.

Still referring to FIG. 1, TIA 1 also includes a total parasitic capacitance that is symbolically referenced as a capacitor symbol labeled 30. The total parasitic capacitance 30 represents the total equivalent parasitic capacitance at the first input terminal 4A of the op-amp 4. The total equivalent parasitic capacitance symbolized by total parasitic capacitance 30 is contributed to at least one sensor junction capacitance (e.g., photodiode junction capacitance), PCB trace capacitance, input differential and common mode capacitance generated from the op-amp 4, solid state switch capacitance, and other electrical components and/or device electrically connected with the TIA 1 that may contribute parasitic capacitance.

Still referring to FIG. 1, TIA 1 includes a second feedback network 40. In the present disclosure, the second feedback network 40 and the op-amp 4 are electrically connected in parallel with one another in TIA 1. The second feedback network 40 and the T-network 20 are also electrically connected in parallel with one another in TIA 1. In the present disclosure, the second feedback network 40 is also separate from the T-network 20, including the first impedance network 22 and the two impedance network 24. The second feedback network 40 is capable of managing the DC input common mode voltage applied by the input voltage source architecture 10 which is then amplified by the DC noise gain of the TIA 1.

As seen in FIG. 1, the second feedback network 40 is electrically connected with the op-amp 4, via the eighth electrical connection W8 and a fifteenth electrical connection W15, where the output terminal 4E of the op-amp 4 is in series with an input of the second feedback network 40. In the illustrated embodiment, the second feedback network 40 includes a third resistor 42 that is electrically connected with the op-amp 4 via the fifteenth electrical connection W15. Particularly, an input terminal of the third resistor 42 of the third resistor 42 is electrically connected with the output terminal 4E of the op-amp 4 via the fifteenth electrical connection W15. The third resistor 42 of the second feedback network 40 also defines a first resistance value “R3” as shown in FIG. 1.

The second feedback network 40 also includes a third capacitor 44 that is electrically connected with the op-amp 4 via the eighth electrical connection W8 and the fifteenth electrical connection W15. Particularly, the third capacitor 44 is electrically connected with the output terminal 4E of the op-amp 4, via the eighth electrical connection W8 and the fifteenth electrical connection W15, at the input terminal of the third capacitor 44. The third capacitor 44 of the first impedance network 22 also defines a third capacitance value “C3” as shown in FIG. 1.

Still referring to FIG. 1, the third resistor 42 and the third capacitor 44 of the second feedback network 40 are also electrically connected in parallel with one another via an sixteenth electrical connection W16 and a seventeenth electrical connection W17. Specifically, the sixteenth electrical connection W16 electrically connects the input terminal of the third resistor 42 with the input terminal of the third capacitor 44, and the seventeenth electrical connection W17 electrically connects an output terminal of the third resistor 42 with an output terminal of the third capacitor 44.

In the present disclosure, the second feedback network 40 may also include a third parasitic capacitance (not illustrated) that is generated within the second feedback network 40 by the third capacitor 44. The third parasitic capacitance of the third capacitor 44 is a third parasitic capacitance value which is less than the third capacitance value C3 of the third capacitor 44.

Still referring to FIG. 1, TIA 1 also includes a fourth switch 46 that is electrically connected with the T-network 20. Particularly, the fourth switch 46 is electrically connected with the second feedback network 40 via an eighteenth electrical connection W18 where an input terminal of the fourth switch 46 is in series with the output terminal of the second feedback network 40. The fourth switch 46 is also electrically connected with the first input terminal 4A of the op-amp 4 via the first electrical connection W1, the fourteenth electrical connection W14, and a nineteenth electrical connection W19 where an output terminal of the fourth switch 46 is in series with the first input terminal 4A of the op-amp 4.

In operation, the second feedback network 40 may electrically communicate with the first input terminal 4A of the op-amp 4 based on the electrical state of the fourth switch 46. In one instance, the second feedback network 40 electrically communicates with the first input terminal 4A of the op-amp 4, via the first electrical connection W1, the fourteenth electrical connection W14, and the nineteenth electrical connection W19, when the fourth switch 46 is provided in a closed state. In another instance, the second feedback network 40 is impeded from electrically communicating with the first input terminal 4A of the op-amp 4, via the first electrical connection W1, the fourteenth electrical connection W14, and the nineteenth electrical connection W19, when the fourth switch 46 is provided in an open state.

Still referring to FIG. 1, TIA 1 also includes a set of controllers 50 that electrically connects with the first switch 12, the second switch 16, the third switch 28, and the fourth switch 46. As discussed in greater detail below, the set of controllers 50 is configured to actuate one or more of the first switch 12, the second switch 16, the third switch 28, and the fourth switch 46 between closed states and open states for utilizing one or more of the first input common mode voltage source 14, the second input common mode voltage source 18, the T-network 20, and the second feedback network 40.

The set of controllers 50 includes a first controller 52. As best seen in FIG. 1, the first controller 52 is electrically connected with the first switch 12 via a twentieth electrical connection W20. The first controller 52 is configured to actuate the first switch 12 between a closed state and an open state for enabling electrical communication between the second input terminal 4B of the op-amp 4 and the first input common mode voltage source 14. The first controller 52 is also electrically connected with the fourth switch 46 via a twenty-first electrical connection W21. The first controller 52 is also configured to actuate the fourth switch 46 between a closed state and an open state for enabling electrical communication between the first input terminal 4A of the op-amp 4 and the second feedback network 40.

In operation, the first controller 52 is configured to actuate the first switch 12 and the fourth switch 46 concurrently. In one instance, the first controller 52 may send a first signal or pulse to the first switch 12 to actuate the first switch 12 to the closed state to enable electrical communication between the op-amp 4 (at the second input terminal 4B) and the first input common mode voltage source 14. Concurrently, the first controller 52 may send the same first signal or pulse to the fourth switch 46 to actuate the fourth switch 46 to the closed state to enable electrical communication between the op-amp 4 (at the first input terminal 4A) and the second feedback network 40. In another instance, the first controller 52 may send a second signal or pulse to the first switch 12 to actuate the first switch 12 to the open state to disable electrical communication between the op-amp 4 (at the second input terminal 4B) and the first input common mode voltage source 14. Concurrently, the first controller 52 may also send the same second signal or pulse to the fourth switch 46 to actuate the fourth switch 46 to the open state to disable electrical communication between the op-amp 4 (at the first input terminal 4A) and the second feedback network 40.

The set of controllers 50 includes a second controller 54. As best seen in FIG. 1, the second controller 54 is electrically connected with the second switch 16 via a twenty-second electrical connection W22. The second controller 54 is configured to actuate the second switch 16 between a closed state and an open state for enabling electrical communication between the second input terminal 4B of the op-amp 4 and the second input common mode voltage source 18. The second controller 54 is also electrically connected with the third switch 28 via a twenty-third electrical connection W23. The second controller 54 is also configured to actuate the third switch 28 between a closed state and an open state for enabling electrical communication between the first input terminal 4A of the op-amp 4 and the T-network 20.

In operation, the second controller 54 is configured to actuate the second switch 16 and the third switch 28 concurrently. In one instance, the second controller 54 may send a first signal or pulse to the second switch 16 to actuate the second switch 16 to the closed state to enable electrical communication between the op-amp 4 (at the second input terminal 4B) and the second input common mode voltage source 18. Concurrently, the second controller 54 may send the same first signal or pulse to the third switch 28 to actuate the third switch 28 to the closed state to enable electrical communication between the op-amp 4 (at the first input terminal 4A) and the T-network 20. In another instance, the second controller 54 may send a second signal or pulse to the second switch 16 to actuate the second switch 16 to the open state to disable electrical communication between the op-amp 4 (at the second input terminal 4B) and the second input common mode voltage source 18. Concurrently, the second controller 54 may also send the same second signal or pulse to the third switch 28 to actuate the third switch 28 to the open state to disable electrical communication between the op-amp 4 (at first input terminal 4A) and the T-network 20.

Such inclusion of switches 12, 16, 28, 46 with the input voltage source architecture 10, the T-network 20, and the second feedback network 40 is considered advantageous at least because the actions of switching between the T-network 20 and the second feedback network 40 maintains a fixed output DC bias under all gain configurations provided in TIA 1. Suh benefits of achieving a fixed DC output bias voltage will provide a greater achievable voltage headroom on the output of the op-amp 4 to maximize the achievable signal-to-noise ratio (SNR) and dynamic range of the TIA 1.

Such inclusion of the set of controllers 50 is also considered advantageous at least because the set of controllers 50 may be programmed to actuate the first switch 12, the second switch 16, the third switch 28, and the fourth switch 46 based on the input current signal senses and outputted by the at least one sensor 2. In one instance, the first controller 52 may actuate the first switch 12 and the fourth switch 46 from open states to closed states while the second controller 54 maintains the second switch 16 and the third switch 28 at open state when TIA 1 senses a first input current signal having a first magnitude or amplitude outputted by the at least one sensor 2. In another instance, second controller 54 may actuate the second switch 16 and the third switch 28 from open states to closed states while the first controller 52 actuates the second switch 16 and the third switch 28 from open states to closed states when TIA 1 senses a second input current signal having a second magnitude or amplitude outputted by the at least one sensor 2 that is less than the first input current signal having the first magnitude.

Having now described the components of the TIA 1, a method of using TIA 1 to amplify electrical current output from the at least one sensor 2 through is described in more detail below.

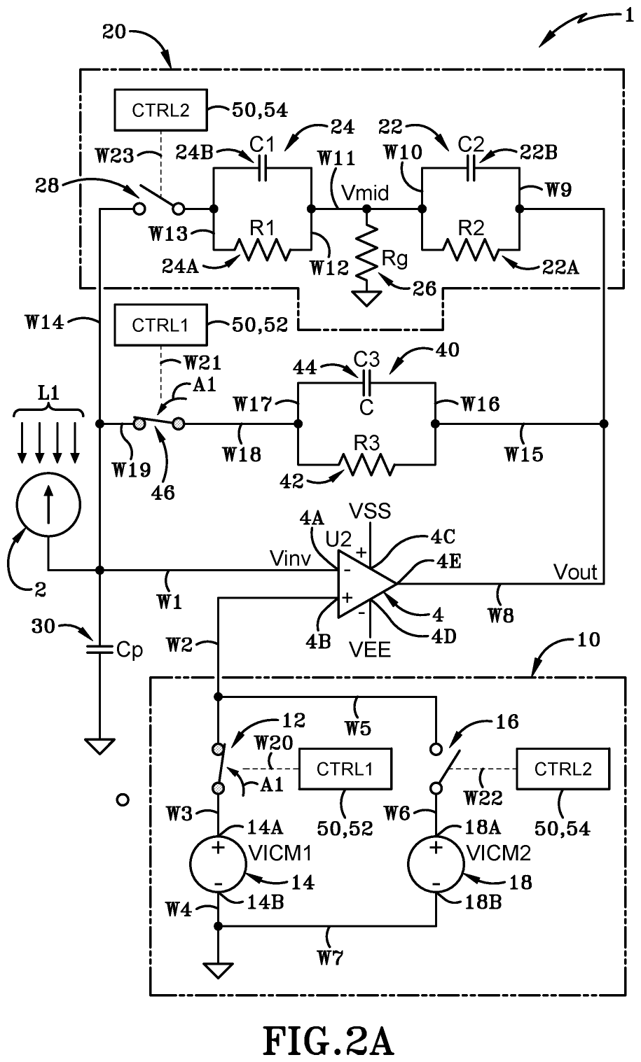

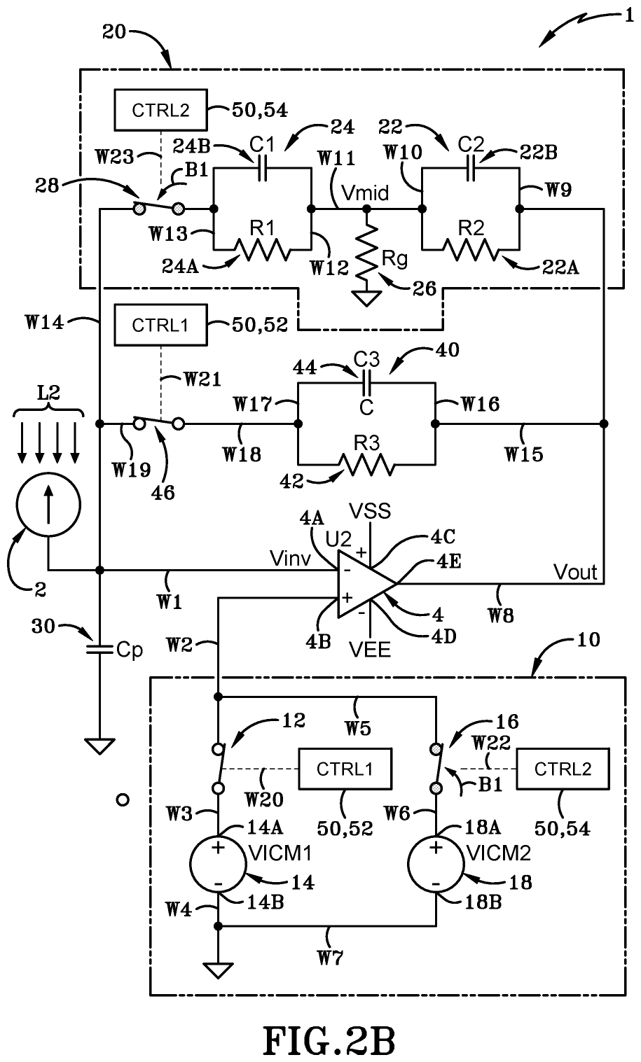

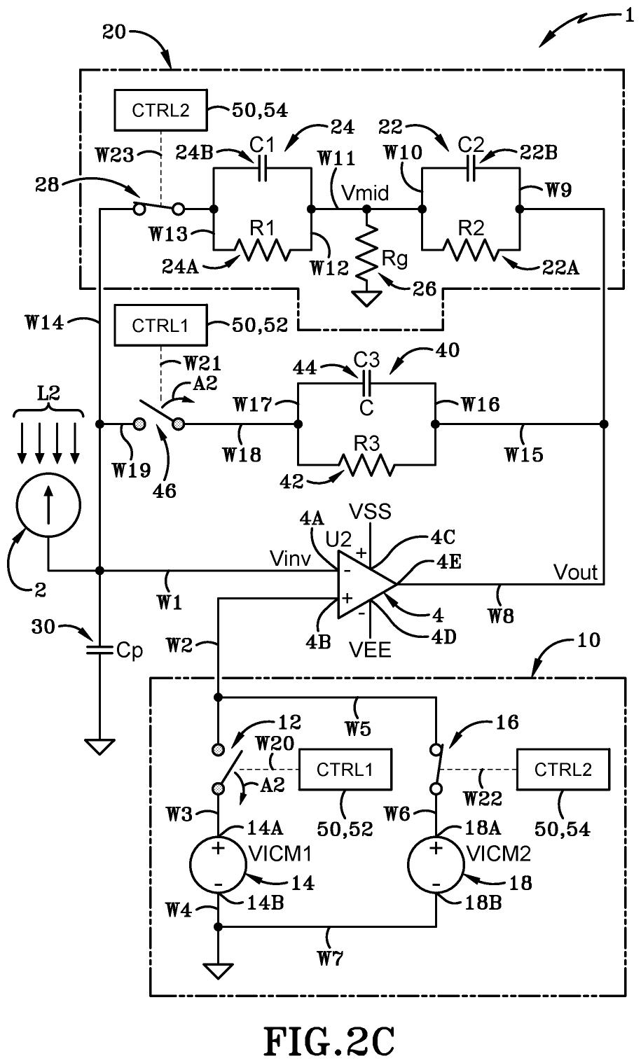

In operation, the at least one sensor 2 is configured to detect and gather data for a desired purpose based on the configuration of the at least one sensor 2 (see FIG. 2A). In one instance, and as best seen in FIG. 2A, the at least one sensor 2 is a photodiode that detects and captures a first light source (denoted by an arrow labeled “L1” in FIG. 2A) for a desired purpose. Upon capturing, the at least one sensor 2 converts this data (e.g., the first light source) into a first current signal. The first current signal of the at least one sensor 2 is then outputted to the first input terminal 4A of the op-amp 4 via the first electrical connection W1. The first current signal outputted to the op-amp 4 is then converted from the first current signal to a first voltage signal via the properties and configurations of the ideal op-amp 4 in conjunction with the T-network 20.

Once the first current signal is converted to the first voltage signal, the set of controllers 50 may provide each the first switch 12, the second switch 16, the third switch 28, and the fourth switch 46 at a desired electrical state based on the value of the first voltage signal. Prior to initiating and/or using TIA 1, the first switch 12, the second switch 16, the third switch 28, and the fourth switch 46 are shown in an open state. As best seen in FIG. 2A, the first controller 52 sends a first signal or pulse to the first switch 12 to actuate the first switch 12 from an open state to a closed state; such actuation of the first switch 12 by first controller 52 is denoted by an arrow labeled “A1” as shown in FIG. 2A. Concurrently, the first controller 52 also sends the same first signal or pulse to the fourth switch 46 to actuate the fourth switch 46 from an open state to a closed state; such actuation of the fourth switch 46 by first controller 52 is denoted by an arrow labeled “A1” as shown in FIG. 2A.

At this stage, the second controller 54 maintains the second switch 16 at the open state to impede a second input common mode voltage signal to be outputted to the second input terminal 4B of the op-amp 4 by the second input common mode voltage source 18. The second controller 54 also maintains the second switch 16 at the open state to impede the T-network 20 from outputting a signal to the first input terminal 4A of the op-amp 4.

Once the first controller 52 actuates each of the first switch 12 and the fourth switch 46 to the closed position, the first input common mode voltage source 14 outputs a first input common mode voltage signal to the second input terminal 4B of the op-amp 4 by the second electrical connection W2 and the third electrical connection W3. Such use of the first input common mode voltage signal assists in the prevention of generating distorted output signals in TIA 1 by managing the input voltage being delivered into the op-amp 4 during operation due to potential saturation problems with single supply applications, operating outside input voltage range or common mode range specifications, and clipping from second stage downstream circuitry.

Once the first current signal is converted to a first voltage signal via the op-amp 4, the op-amp 4 then outputs the first voltage signal at a first gain value to the second feedback network 40. Specifically, the first voltage signal is outputted from the output terminal 4E of the op-amp 4 to the input terminal of the second feedback network 40 via the eighth electrical connection W8 and the fifteenth electrical connection W15. Once the first voltage signal is outputted to the second feedback network 40, the voltage signal then travels through the third resistor 42 and the third capacitor 44 of the second feedback network 40. Upon traveling through the second feedback network 40, the second feedback network 40 outputs the first voltage signal at a second gain value based on the third resistance value “R3” of the third resistor 42 and the third capacitance value “C3” and the third capacitor 44 of the second feedback network 40.

One the first voltage signal is outputted from the second feedback network 40 at the second gain value, the first voltage signal with the second gain value is feed back into the op-amp 4 via the first electrical connection W1. Specifically, the first voltage signal with the second gain value is outputted from the output of the second feedback network 40 to the first input terminal 4A of the op-amp 4 via the first electrical connection W1. It should be understood that this process and/or stage implemented by the first controller 52 may be repeated for a desired amount of time or cycles in TIA 1 until the at least one sensor 2 ceases to receiving data and converting said data into input current signals. It should also be understood that this process and/or stage implemented by the first controller 52 may be repeated for a desired amount of time or cycles in TIA 1 at which the first voltage signal may be provided at this specific gain value based on the use of the first input common mode voltage source 14 and the second feedback network 40 until the input current signal received at the at least one sensor 2 changes and/or is less than the current input current signal discussed previously.

In another instance, and as best seen in FIGS. 2B-2C, the at least one sensor 2 may detect and capture a second light source (denoted by arrow labeled “L2” in FIGS. 2B-2C) for a desired purpose. Upon capturing, the at least one sensor 2 converts this data (e.g., second light source) into a second current signal. In this instance, the second current signal derived from the second light source defines a second magnitude that is less than a first magnitude defined by the first current signal discussed above. Stated differently, the second current signal derived from the second light source defines a second amplitude that is less than a first amplitude of the first current signal discussed above. The second current signal of the at least one sensor 2 is then outputted to the first input terminal 4A of the op-amp 4 via the first electrical connection W1. The second current signal outputted to the op-amp 4 is then converted from the second current signal to a second voltage signal via the properties and configurations of the ideal op-amp 4 in conjunction with the T-network 20.

Once the second current signal is converted to the second voltage signal, the set of controllers 50 may provide each the first switch 12, the second switch 16, the third switch 28, and the fourth switch 46 at a desired electrical state based on the value of the second voltage signal. In this instance, the second voltage signal has a magnitude that is less than the magnitude of the first voltage signal previously discussed. Upon such recognition, TIA 1 may instruct the second controller 54 to send a first signal or pulse to the second switch 16 to actuate the second switch 16 from an open state to a closed state to electrical connect the op-amp 4 (particularly the second input terminal 4B) and second input common mode voltage source 18 with one another; such actuation of the second switch 16 by second controller 54 is denoted by an arrow labeled “B1” as shown in FIG. 2B. Concurrently, the second controller 54 also sends the same first signal or pulse to the third switch 28 to actuate the third switch 28 from an open state to a closed state to electrical connect the op-amp 4 (particularly the first input terminal 4A) and T-network 20 with one another; such actuation of the third switch 28 by second controller 54 is denoted by an arrow labeled “B1” as shown in FIG. 2B.

At this stage, the first controller 52 briefly maintains the first switch 12 and the fourth switch 46 at the closed states until the second controller 54 actuates the second switch 16 and the third switch 28 from open states to closed states. Once the second switch 16 and the third switch 28 are actuated to closed states, the first controller 52 may then actuate the first switch 12 from the closed state to the open state; such actuation of the first switch 12 by first controller 52 is denoted by an arrow labeled “A2” as shown in FIG. 2C. Such actuation of the first switch 12 from the closed state to the open state impedes a first input common mode voltage signal to be outputted to the second input terminal 4B of the op-amp 4 by the first input common mode voltage source 14. Concurrently, the first controller 52 may also actuate the fourth switch 46 from the closed state to the open state; such actuation of the fourth switch 46 by first controller 52 is denoted by an arrow labeled “A2” as shown in FIG. 2C. Such actuation of the fourth switch 46 from the closed state to the open state impedes the second feedback network 40 from outputting a signal to the first input terminal 4A of the op-amp 4.

Once the second controller 54 actuates each of the second switch 16 and the third switch 28 to the closed position, the second input common mode voltage source 18 outputs a second input common mode voltage signal to the second input terminal 4B of the op-amp 4 by the second electrical connection W2, the fifth electrical connection W5, and the sixth electrical connection W6. Such use of the second input common mode voltage signal assists in the prevention of generating distorted output signals in TIA 1 by managing the input voltage being delivered into the op-amp 4 during operation due to potential saturation problems with single supply applications, operating outside input voltage range or common mode range specifications, and clipping from second stage downstream circuitry.

Once the second current signal is converted to the second voltage signal via the op-amp 4, the op-amp 4 outputs the second voltage signal at a first gain value to the T-network feedback architecture 20. Specifically, the second voltage signal is outputted from the output terminal 4E of the op-amp 4 to the input terminal of the first impedance network 22 via the eighth electrical connection W8. Once the second voltage signal is outputted to the first impedance network 22, the second voltage signal then travels through the first resistor 22A and the first capacitor 22B of the first impedance network 22. Upon traveling through the first impedance network 22, the first impedance network 22 outputs the second voltage signal at a second gain value based on the first resistance value “R1” and the first capacitance value “C1” of the first resistor 22A and the first capacitor 22B of the first impedance network 22. At this stage, the second gain value of the second voltage signal outputted by the first impedance network 22 is different than the first gain value of the second voltage signal outputted by the op-amp 4 when measured at location Vmid.

Once the second voltage signal is outputted from the first impedance network 22 at the second gain value, the second voltage signal is then outputted to the ground resistor 26 and to the second impedance network 24 via the eleventh electrical connection W11. Specifically, the second voltage signal with the second gain value is outputted from an output of the first impedance network 22 to an input of the second impedance network 24 via the eleventh electrical connection W11. Once the second voltage signal is outputted to the second impedance network 24, the second voltage signal then travels through the second resistor 24A and the second capacitor 24B of the second impedance network 24. Upon traveling through the second impedance network 24, the second impedance network 24 outputs the second voltage signal at a third gain value based on the second resistance value “R2” and the second capacitance value “C2” of the second resistor 24A and the second capacitor 24B of the second impedance network 24; the second voltage signal at the third gain value is different than the second voltage signal at the second gain value when measured at location Vmid. Additionally, the second voltage signal of the second gain value outputted from the first impedance network 22 travels through the ground resistor 26 which includes the third resistance value “Rg.”

One the second voltage signal is outputted from the second impedance network 24 at the third gain value, the second voltage signal with the third gain value is feed back into the op-amp 4 via the first electrical connection W1. Specifically, the second voltage signal with the third gain value is outputted from an output of the second impedance network 24 to the first input terminal 4A of the op-amp 4 via the first electrical connection W1.

It should be understood that this process and/or stage implemented by the first controller 52 may be repeated for a desired amount of time or cycles in TIA 1 until the at least one sensor 2 ceases to receiving data and converting said data into input current signals. It should also be understood that this process and/or stage implemented by the first controller 52 may be repeated for a desired amount of time or cycles in TIA 1 at which the first voltage signal may be provided at this specific gain value based on the use of the first input common mode voltage source 14 and the second feedback network 40 until the input current signal received at the at least one sensor 2 changes and/or is less than the current input current signal discussed previously.

It should also be understood that the process of actuating the first switch 12, the second switch 16, the third switch 28, and the fourth switch 46 between open states and closed states by the set of controllers 50 may be repeated for a desired amount of time or cycles in TIA 1 based on the gain values and bandwidth values of voltage signals received and outputted by op-amp 4. As discussed previously, TIA 1 with the T-network feedback architecture 20 enables the use of allowing high gain and high bandwidth signals by mitigating the issues of parasitic capacitances associated with components provided in TIA 1 and/or devices electrically connected with TIA 1.

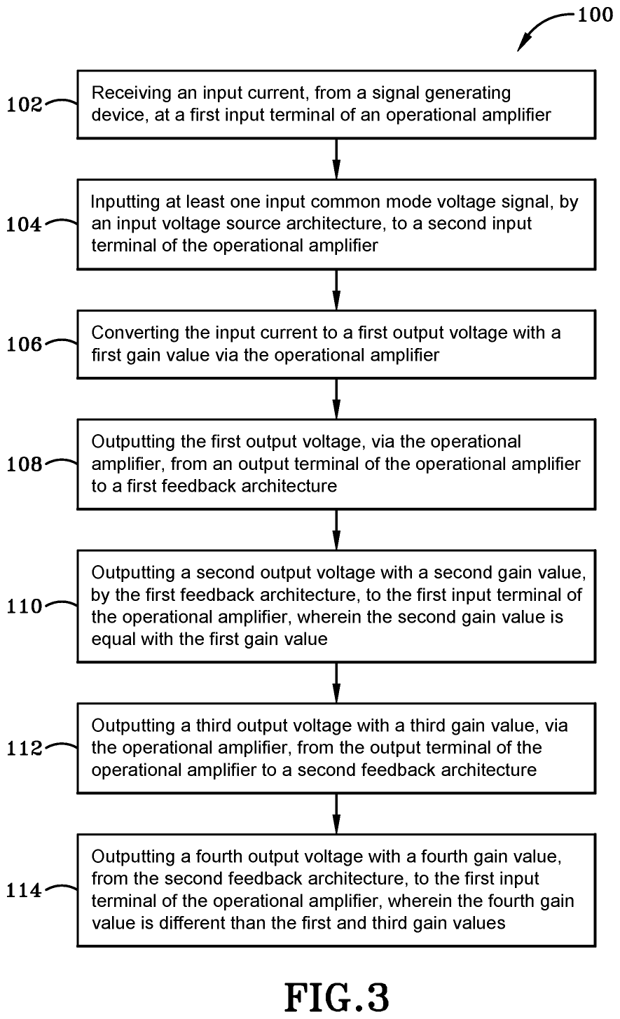

FIG. 3 illustrates a method 100. An initial step 102 of method 100 includes receiving an input current, from a signal generating device, at a first input terminal of an operational amplifier. Another step 104 of method 100 includes inputting at least one input common mode voltage signal, by an input voltage source architecture, to a second input terminal of the operational amplifier. Another step 106 of method 100 includes converting the input current to a first output voltage with a first gain value via the operational amplifier. Another step 108 of method 100 includes outputting the first output voltage, via the operational amplifier, from an output terminal of the operational amplifier to a first feedback architecture. Another step 110 of method 100 includes outputting a second output voltage with a second gain value, by the first feedback architecture, to the first input terminal of the operational amplifier, wherein the second gain value is equal with the first gain value. Another step 112 of method 100 includes outputting a third output voltage with a third gain value, via the operational amplifier, from the output terminal of the operational amplifier to a second feedback architecture. Another step 114 of method 100 includes outputting a fourth output voltage with a fourth gain value, from the second feedback architecture, to the first input terminal of the operational amplifier, wherein the fourth gain value is different than the first and third gain values.

In other exemplary embodiments, method 100 may include optional and/or further steps. In one exemplary embodiment, method 100 may further include steps of actuating a first set of switches, via at least one controller, from open states to closed states; and maintaining a second set of switches, via at least another controller, at open states. In another exemplary embodiment, method 100 may further include that the step of actuating the first set of switches further comprises: actuating a first switch of the first set of switches, via the at least one controller, from a first open state to a first closed state, to provide electrical communication between the operational amplifier and a first input common mode voltage source of the input voltage source architecture; and actuating a second switch of the first set of switches, via the at least one controller, from a second open state to a second closed state, to provide electrical communication between the operational amplifier and the first feedback architecture. In another exemplary embodiment, method 100 may further include steps of maintaining the first set of switches, via at least one controller, at open states; and actuating the second set of switches, via the at least another controller, from the open states to closed states. In another exemplary embodiment, method 100 may further include that the step of actuating the second set of switches further comprises: actuating a first switch of the second set of switches, via the at least another controller, from a first open state to a first closed state, to provide electrical communication between the operational amplifier and a second input common mode voltage source of the input voltage source architecture; and actuating a second switch of the second set of switches, via the at least another controller, from a second open state to a second closed state, to provide electrical communication between the operational amplifier and the second feedback architecture In another exemplary embodiment, method 100 may further include steps of actuating the first set of switches, via the at least one controller, from the closed states to the opened states; and maintaining a second set of switches, via at least another controller, at the closed states. In another exemplary embodiment, method 100 may further include that the step of actuating the first set of switches further comprises: actuating a first switch of the first set of switches, via the at least one controller, from a first open state to a first closed state, to impede electrical communication between the operational amplifier and a first input common mode voltage source of the input voltage source architecture; and actuating a second switch of the first set of switches, via the at least one controller, from a second open state to a second closed state, to impede electrical communication between the operational amplifier and the first feedback architecture.

Various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The above-described embodiments can be implemented in any of numerous ways. For example, embodiments of technology disclosed herein may be implemented using hardware, software, or a combination thereof. When implemented in software, the software code or instructions can be executed on any suitable processor or collection of processors, whether provided in a single computer or distributed among multiple computers. Furthermore, the instructions or software code can be stored in at least one non-transitory computer readable storage medium.

Also, a computer or smartphone may be utilized to execute the software code or instructions via its processors may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format.

Such computers or smartphones may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

The various methods or processes outlined herein may be coded as software/instructions that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, various inventive concepts may be embodied as a computer readable storage medium (or multiple computer readable storage media) (e.g., a computer memory, one or more floppy discs, compact discs, optical discs, magnetic tapes, flash memories, USB flash drives, SD cards, circuit configurations in Field Programmable Gate Arrays or other semiconductor devices, or other non-transitory medium or tangible computer storage medium) encoded with one or more programs that, when executed on one or more computers or other processors, perform methods that implement the various embodiments of the disclosure discussed above. The computer readable medium or media can be transportable, such that the program or programs stored thereon can be loaded onto one or more different computers or other processors to implement various aspects of the present disclosure as discussed above.

The terms “program” or “software” or “instructions” are used herein in a generic sense to refer to any type of computer code or set of computer-executable instructions that can be employed to program a computer or other processor to implement various aspects of embodiments as discussed above. Additionally, it should be appreciated that according to one aspect, one or more computer programs that when executed perform methods of the present disclosure need not reside on a single computer or processor, but may be distributed in a modular fashion amongst a number of different computers or processors to implement various aspects of the present disclosure.

Computer-executable instructions may be in many forms, such as program modules, executed by one or more computers or other devices. Generally, program modules include routines, programs, objects, components, data structures, etc. that perform particular tasks or implement particular abstract data types. Typically, the functionality of the program modules may be combined or distributed as desired in various embodiments. As such, one aspect or embodiment of the present disclosure may be a computer program product including least one non-transitory computer readable storage medium in operative communication with a processor, the storage medium having instructions stored thereon that, when executed by the processor, implement a method or process described herein, wherein the instructions comprise the steps to perform the method(s) or process(es) detailed herein.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

All definitions, as defined and used herein, should be understood to control over dictionary definitions, definitions in documents incorporated by reference, and/or ordinary meanings of the defined terms.

“Logic”, as used herein, includes but is not limited to hardware, firmware, software, and/or combinations of each to perform a function(s) or an action(s), and/or to cause a function or action from another logic, method, and/or system. For example, based on a desired application or needs, logic may include a software controlled microprocessor, discrete logic like a processor (e.g., microprocessor), an application specific integrated circuit (ASIC), a programmed logic device, a memory device containing instructions, an electric device having a memory, or the like. Logic may include one or more gates, combinations of gates, or other circuit components. Logic may also be fully embodied as software. Where multiple logics are described, it may be possible to incorporate the multiple logics into one physical logic. Similarly, where a single logic is described, it may be possible to distribute that single logic between multiple physical logics.

Furthermore, the logic(s) presented herein for accomplishing various methods of this system may be directed towards improvements in existing computer-centric or internet-centric technology that may not have previous analog versions. The logic(s) may provide specific functionality directly related to structure that addresses and resolves some problems identified herein. The logic(s) may also provide significantly more advantages to solve these problems by providing an exemplary inventive concept as specific logic structure and concordant functionality of the method and system. Furthermore, the logic(s) may also provide specific computer implemented rules that improve on existing technological processes. The logic(s) provided herein extends beyond merely gathering data, analyzing the information, and displaying the results. Further, portions or all of the present disclosure may rely on underlying equations that are derived from the specific arrangement of the equipment or components as recited herein. Thus, portions of the present disclosure as it relates to the specific arrangement of the components are not directed to abstract ideas. Furthermore, the present disclosure and the appended claims present teachings that involve more than performance of well-understood, routine, and conventional activities previously known to the industry. In some of the method or process of the present disclosure, which may incorporate some aspects of natural phenomenon, the process or method steps are additional features that are new and useful.

The articles “a” and “an,” as used herein in the specification and in the claims, unless clearly indicated to the contrary, should be understood to mean “at least one.” The phrase “and/or,” as used herein in the specification and in the claims (if at all), should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc. As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

While components of the present disclosure are described herein in relation to each other, it is possible for one of the components disclosed herein to include inventive subject matter, if claimed alone or used alone. In keeping with the above example, if the disclosed embodiments teach the features of components A and B, then there may be inventive subject matter in the combination of A and B, A alone, or B alone, unless otherwise stated herein.

As used herein in the specification and in the claims, the term “effecting” or a phrase or claim element beginning with the term “effecting” should be understood to mean to cause something to happen or to bring something about. For example, effecting an event to occur may be caused by actions of a first party even though a second party actually performed the event or had the event occur to the second party. Stated otherwise, effecting refers to one party giving another party the tools, objects, or resources to cause an event to occur. Thus, in this example a claim element of “effecting an event to occur” would mean that a first party is giving a second party the tools or resources needed for the second party to perform the event, however the affirmative single action is the responsibility of the first party to provide the tools or resources to cause said event to occur.

When a feature or element is herein referred to as being “on” another feature or element, it can be directly on the other feature or element or intervening features and/or elements may also be present. In contrast, when a feature or element is referred to as being “directly on” another feature or element, there are no intervening features or elements present. It will also be understood that, when a feature or element is referred to as being “connected”, “attached” or “coupled” to another feature or element, it can be directly connected, attached or coupled to the other feature or element or intervening features or elements may be present. In contrast, when a feature or element is referred to as being “directly connected”, “directly attached” or “directly coupled” to another feature or element, there are no intervening features or elements present. Although described or shown with respect to one embodiment, the features and elements so described or shown can apply to other embodiments. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “above”, “behind”, “in front of”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly”, “downwardly”, “vertical”, “horizontal”, “lateral”, “transverse”, “longitudinal”, and the like are used herein for the purpose of explanation only unless specifically indicated otherwise.

Although the terms “first” and “second” may be used herein to describe various features/elements, these features/elements should not be limited by these terms, unless the context indicates otherwise. These terms may be used to distinguish one feature/element from another feature/element. Thus, a first feature/element discussed herein could be termed a second feature/element, and similarly, a second feature/element discussed herein could be termed a first feature/element without departing from the teachings of the present invention.

An embodiment is an implementation or example of the present disclosure. Reference in the specification to “an embodiment,” “one embodiment,” “some embodiments,” “one particular embodiment,” “an exemplary embodiment,” or “other embodiments,” or the like, means that a particular feature, structure, or characteristic described in connection with the embodiments is included in at least some embodiments, but not necessarily all embodiments, of the invention. The various appearances “an embodiment,” “one embodiment,” “some embodiments,” “one particular embodiment,” “an exemplary embodiment,” or “other embodiments,” or the like, are not necessarily all referring to the same embodiments.

If this specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein in the specification and claims, including as used in the examples and unless otherwise expressly specified, all numbers may be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical range recited herein is intended to include all sub-ranges subsumed therein.

Additionally, the method of performing the present disclosure may occur in a sequence different than those described herein. Accordingly, no sequence of the method should be read as a limitation unless explicitly stated. It is recognizable that performing some of the steps of the method in a different order could achieve a similar result.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures.

To the extent that the present disclosure has utilized the term “invention” in various titles or sections of this specification, this term was included as required by the formatting requirements of word document submissions pursuant the guidelines/requirements of the United States Patent and Trademark Office and shall not, in any manner, be considered a disavowal of any subject matter.

In the foregoing description, certain terms have been used for brevity, clearness, and understanding. No unnecessary limitations are to be implied therefrom beyond the requirement of the prior art because such terms are used for descriptive purposes and are intended to be broadly construed.

Moreover, the description and illustration of various embodiments of the disclosure are examples and the disclosure is not limited to the exact details shown or described.

What is claimed is:

1. A transimpedance amplifier system, comprising:
an operational amplifier having a first input terminal, a second input terminal, and an output terminal;
a first feedback architecture operatively connected with the operational amplifier at the first input terminal of the operational amplifier and the output terminal of the operational amplifier, the first feedback architecture having a first impedance network and a second impedance network;
a second feedback architecture operatively connected with the operational amplifier at the first input terminal of the operational amplifier and the output terminal of the operational amplifier;
an input voltage source architecture operatively connected with the second input terminal of the operational amplifier; and
at least one controller operatively connected with each of the first feedback architecture, the second feedback architecture, and the input voltage source architecture;
wherein the at least one controller is configured to switch each of the first feedback architecture, the second feedback architecture, and the input voltage source architecture between an operative state and an inoperative state to achieve a predetermined fixed output bias voltage from the operational amplifier.

2. The system of claim 1, further comprising:
a first set of switches operatively connected with a first input common voltage power source of the input voltage source architecture, the second feedback architecture, and the at least one controller; and
a second set of switches operatively connected with the first feedback architecture, a second input common voltage power source of the input voltage source architecture, and at least another controller.

3. The system of claim 2, further comprising:
a first input common mode voltage outputted from the first input common voltage power source to the operational amplifier and the second feedback architecture when the at least one controller switches the first set of switches from open states to closed states;
wherein the second feedback architecture and the first input common voltage power source are in the operative state.

4. The system of claim 3, further comprising:
an output voltage outputted from the operational amplifier and the second feedback architecture;
wherein the first input common mode voltage and the output voltage are equal to one another.

5. The system of claim 3, further comprising:
a second input common mode voltage outputted from the second input common voltage power source to the operational amplifier and the first feedback architecture when the at least another controller switches the second set of switches from open states to closed states;
wherein the first feedback architecture and the second input common voltage power source are in the operative state.

6. The system of claim 5, further comprising:
an output voltage that is output from the operational amplifier and the second feedback architecture;
wherein the second input common mode voltage and the output voltage are different from one another.

7. The system of claim 2, wherein the first set of switches comprises:
a first switch operatively connected with and in series with an output terminal of the first input common voltage power source and operatively connected with the second input terminal of the operational amplifier; and
a second switch operatively connected with and in series with an output terminal of the second feedback architecture and operatively connected with the first input terminal of the operational amplifier;
wherein the first switch and the second switch are configured to be switched concurrently between open states and closed states.

8. The system of claim 7, wherein the second feedback architecture comprises:
a capacitor operatively connected with the output terminal of the operational amplifier; and
a resistor operatively connected with the output terminal of the operational amplifier;
wherein the capacitor and the resistor are in parallel with one another, and the capacitor and the resistor are in series with the second switch.

9. The system of claim 2, wherein the second set of switches comprises:
a first switch operatively connected with and in series with an output terminal of the second input common voltage power source and operatively connected with the second input terminal of the operational amplifier; and
a second switch operatively connected with and in series with an output terminal of the first feedback architecture and operatively connected with the first input terminal of the operational amplifier;
wherein the first switch and the second switch are configured to be switched concurrently between open states and closed states by the at least another controller.

10. The system of claim 9, wherein the first feedback architecture further comprises:
a capacitor of the first impedance network operatively connected with the output terminal of the operational amplifier; and
a resistor of the first impedance network operatively connected with the output terminal of the operational amplifier;
wherein the capacitor of the first impedance network and the resistor of the first impedance network are in parallel with one another, and the capacitor of the first impedance network and the resistor of the first impedance network are in series with the second impedance network and the second switch.

11. The system of claim 10, wherein the first feedback architecture further comprises:
a capacitor of the second impedance network operatively connected with the output terminal of the operational amplifier; and
a resistor of the second impedance network operatively connected with the output terminal of the operational amplifier;
wherein the capacitor of the second impedance network and the resistor of the second impedance network are in parallel with one another, and the capacitor of the second impedance network and the resistor of the second impedance network are in series with the second switch.

12. The system of claim 11, wherein the first feedback architecture further comprises:
a ground resistor operatively connected with an output of the first impedance network and operatively connected with an input of the second impedance network.

13. The system of claim 11, further comprising:
a parasitic capacitor in series with the second feedback architecture and operatively connected with the first input terminal of the operational amplifier.

14. A method comprising the steps of:
receiving an input current, from a signal generating device, at a first input terminal of an operational amplifier;
inputting at least one input common mode voltage signal, by an input voltage source architecture, to a second input terminal of the operational amplifier;
converting the input current to a first output voltage with a first gain value via the operational amplifier;
outputting the first output voltage, via the operational amplifier, from an output terminal of the operational amplifier to a first feedback architecture;
outputting a second output voltage with a second gain value, by the first feedback architecture, to the first input terminal of the operational amplifier, wherein the second gain value is equal with the first gain value;
outputting a third output voltage with a third gain value, via the operational amplifier, from the output terminal of the operational amplifier to a second feedback architecture; and
outputting a fourth output voltage with a fourth gain value, from the second feedback architecture, to the first input terminal of the operational amplifier, wherein the fourth gain value is different than the first and third gain values.

15. The method of claim 14, further comprising:
actuating a first set of switches, via at least one controller, from open states to closed states; and
maintaining a second set of switches, via at least another controller, at open states.

16. The method of claim 15, wherein the step of actuating the first set of switches further comprises:
actuating a first switch of the first set of switches, via the at least one controller, from a first open state to a first closed state, to provide electrical communication between the operational amplifier and a first input common mode voltage source of the input voltage source architecture; and
actuating a second switch of the first set of switches, via the at least one controller, from a second open state to a second closed state, to provide electrical communication between the operational amplifier and the first feedback architecture.

17. The method of claim 15, further comprising:
maintaining the first set of switches, via at least one controller, at open states; and
actuating the second set of switches, via the at least another controller, from the open states to closed states.

18. The method of claim 17, wherein the step of actuating the second set of switches further comprises:
actuating a first switch of the second set of switches, via the at least another controller, from a first open state to a first closed state, to provide electrical communication between the operational amplifier and a second input common mode voltage source of the input voltage source architecture; and
actuating a second switch of the second set of switches, via the at least another controller, from a second open state to a second closed state, to provide electrical communication between the operational amplifier and the second feedback architecture.

19. The method of claim 17, further comprising actuating the first set of switches, via the at least one controller, from the closed states to the opened states; and
maintaining a second set of switches, via at least another controller, at the closed states.

20. The method of claim 19, wherein the step of actuating the first set of switches further comprises:
actuating a first switch of the first set of switches, via the at least one controller, from a first open state to a first closed state, to impede electrical communication between the operational amplifier and a first input common mode voltage source of the input voltage source architecture; and
actuating a second switch of the first set of switches, via the at least one controller, from a second open state to a second closed state, to impede electrical communication between the operational amplifier and the first feedback architecture.
